(19) United States
(12) Patent Application Publication
(10) Pub. No.: US 2012/0061543 A1
(43) Pub. Date: Mar. 15, 2012

(54) ADJUSTABLE FLAT-PANEL DISPLAY MOUNT

(76) Inventor: Landa Juan, Anaheim, CA (US)

(21) Appl. No.: 13/228,234

(22) Filed: Sep. 8, 2011

Related U.S. Application Data
(60) Provisional application No. 61/381,298, filed on Sep. 9, 2010.

(51) Int. Cl. H05K 7/00; F16M 13/02

(52) U.S. Cl. 248/292.11; 248/291.1; 248/292.13

(57) ABSTRACT

An adjustable flat-panel display mount is described. The display mount includes a mounting plate for mounting with a surface, such as a wall. A front mount is included. The front mount is formed to attach with a television display and affix the television display with the display mount. A swing out apparatus is pivotally connected between the mounting plate and the front mount. The swing out apparatus includes a set of bars that, together with the mounting plate and front mount, form a four-bar linkage. The swing out apparatus is formed to swing the front mount between a retracted position and an extended position, such that motion from the retracted to extended position moves the front mount, and attached television display, out and down.

### PRIORITY CLAIM

This is a non-provisional patent application of U.S. Provisional Application No. 61/381,298, filed, Sep. 9, 2010, entitled, “Adjustable Flat-Panel Display Mount System.”

### BACKGROUND OF THE INVENTION

(1) Field of Invention

The present invention relates to a display mount and, more particularly, to an adjustable flat-panel display mount for mounting the flat-panel display to a surface and adjusting the viewing direction and position of the flat-panel display.

(2) Description of Related Art

Flat-panel displays are increasingly popular in homes as televisions and/or computer monitors. Advances in technology and reductions in prices have made them increasingly prevalent in homes throughout the United States and abroad. Unlike their bulky and heavier predecessors, most flat-panel displays are wall-mounted. In homes that have a fireplace, a common approach is to mount the flat-panel display over the fireplace mantel. This arrangement is generally more aesthetically pleasing since less pieces of furniture compete with the living room space. The fireplace is also a natural focal point in a living room and furniture is typically arranged to reflect that fact.

Mounting a display over a fireplace often results in the display being in a position that is awkward for viewing and uncomfortable for persons viewing it from a seated position. Viewers can experience neck and shoulder strain from having to tilt their heads for an extended period of time.

Mounting a display over a fireplace leads to an increased viewing distance, which reduces the viewer's ability to appreciate the image detail. Additionally, mounting a display over a fireplace leads to viewing angles that distort the display image by changing the image aspect ratio, thereby reducing the viewer's ability to appreciate the image.

Further, three-dimensional (3-D) televisions are now available on the market. Existing and anticipated 3-D Models are sensitive to viewing angles and viewing distances.

Therefore, in satisfying the need to alter the viewing angle of traditional and 3-D televisions, several types of flat-panel display mounts are available. For example and as shown in FIG. 1, existing display mounts 100 are commonly used to mount a flat-panel display 102 (e.g., television or computer display) over a fireplace 104 or on a wall surface 106. Some allow for adjustments to the distance from the mounting point 108, viewing height 110, and the image distortion angle 112. The distance from the mounting point 108 and viewing height 110 affect the viewer inclination angle 114 and the viewing distance 116.

One type of mount affixes a display to the wall surface 106. Once installed, adjustments cannot be made to the viewing height 110, the distance from the mounting point 108, or the image distortion angle 112. Therefore, the viewing distance 116 and the viewer inclination angle 114 are fixed and cannot be adjusted. Display mounts that do not allow for adjustment to the image distortion angle 112 distort the image aspect ratio and reduce the viewer's 118 ability to appreciate the image.

Another type of mount affixes a flat-panel display 102 to the wall and provides the ability to reduce the image distortion angle 112 by allowing for some rotation 113 along a horizontal axis 115. Once installed, adjustments cannot be made to the distance from the mounting point 108, or the viewing height 110. Therefore, the viewing distance 116 and the viewer inclination angle 114 cannot be adjusted.

Yet another type of mount affixes a flat-panel display 102 to the wall and provides the ability to adjust the distance from the mounting point 108. This type of device also often provides the ability to adjust the image distortion angle 112 along one or more axes. Such a mount enables the viewer 118 to make slight adjustments to the viewing distance 116. However, such existing mounts do not allow for adjustments to the viewing height 110. Therefore, the viewer inclination angle 114 cannot be adjusted.

The display mounts described above do not change the viewing height 110 as they cannot be lowered. Thus, the viewer inclination angle 114 from a seated position remains relatively unchanged. When these display mounts are mounted over a fireplace 104, the viewing height 110 is awkward in that it creates conditions for an uncomfortable viewer inclination angle 114 when viewing the flat-panel display 102 from a seated position. Viewers 118 can experience neck, shoulder, and back strain from having to tilt their heads up for an extended period of time.

As shown in FIG. 2, another type of mount 200 can adjust the viewing height 110 along a linear path 202. This type of mount 200 enables for the raising and lowering of a flat-panel display 102 from a concealed structural location or from a piece of furniture 204. This type of mount 200 generally requires a custom installation to incorporate it into a structure or piece of furniture 204. While operable for adjusting the viewing height 110, as it is lowered it becomes concealed, therefore, it has a negligible impact on viewer inclination angle 114. This type of mount 200 does not have the ability to adjust the image distortion angle 112. Further, neither the viewing distance 116 nor the viewer inclination angle 114 can be adjusted.

As shown in FIG. 3, yet another type of mount 300 can adjust the viewing height 110 of a flat-panel display 102 along a wall surface 106 or mounting point, thereby adjusting the viewing distance 116. Although allowing for adjustment along a linear path 202, this type of device does not have the ability to adjust the distance from the mounting point 108 or the image distortion angle 112. Importantly, such a mount 300 does not lend itself to be mounted over a fireplace 104 because the flat-panel display 102 cannot be lowered below the mantel 302. A benefit of adjusting the viewing height 110 is lost by the fact that the minimum height is still above the fireplace mantel 302. Thus, such a mount 300 generally does not have the ability to adjust the image distortion angle 112.

In use, flat-panel displays 102 are often used for interactive activities such as video game playing. For video game playing and standard uses, it is beneficial to view the flat-panel display 102 at an appropriate image distortion angle 112, viewer inclination angle 114, and viewing distance 116.

Thus, a continuing need exists for an adjustable flat-panel display mount that enables a display's position to be adjusted vertically as it is simultaneously moved away from the mounting point to avoid fixtures or other obstacles in its path.

### SUMMARY OF INVENTION

While considering the failure of others to make use of all of the above components in this technology space, the inventor unexpectedly realized that an adjustable display mount with an appropriately formed swing out apparatus (e.g., employing a four-bar linkage) would enable the mount to adjust the display vertically as it is simultaneously moved away from the mounting point to avoid fixtures or other obstacles.

Providing the ability to adjust the viewing height enables the viewer to adjust the height of the display to better suit a variety of activities. The viewing height can be decreased to view the display while seated and the viewing height can be increased to view the display while engaged in activities that are better performed while standing, such as interacting with video games or exercise videos.

The display mount includes a mounting plate for mounting with a surface, such as a wall. A front mount is included. The front mount is formed to attach with a flat-panel display (e.g., television display) and affix the flat-panel display with the display mount. A swing out apparatus is pivotally connected between the mounting plate and the front mount. As noted above, the swing out apparatus includes a set of bars that, together with the mounting plate and front mount, form a four-bar linkage. The swing out apparatus is formed to swing the front mount between a retracted position and an extended position, such that motion from the retracted to extended position moves the front mount, and attached television display, out and down.

In another aspect, the swing out apparatus further comprises a counterbalancing mechanism. The counterbalancing mechanism provides a counterbalancing force that is substantially equal to a gravitational force exerted by a flat-panel display when mounted on the display mount.

In yet another aspect, the mounting plate has a back portion and selectively positionable leaves. The selectively positionable leaves are formed such that they can be selectively positioned between being substantially planar with a back portion of the mount plate or perpendicular to the back portion of the mount plate, or any relative position therebetween. An example of such leaves include hinged side plates that are pivotally connected with the back portion.

In another aspect, a rear casing is connected to and between the mounting plate and the swing out apparatus. Additionally, a front casing is connected to and between the swing out apparatus and the front mount.

In another aspect, a heat shield is connected with the front mount to shield the television display from heat that may emanate from a fireplace or other heat source.

In yet another aspect, a linear actuator is attached with the swing out apparatus to swing the front mount between a retracted position and an extended position.

Further, a first switch is attached with the front casing. The first switch is operably connected with the linear actuator to allow for control of the linear actuator. Additionally, the first switch is a double-pole, double-throw switch, which is wired to operate the linear actuator in both positive and negative polarities.

A remote control unit is also operably connected with the linear actuator. The remote control unit is controlled wirelessly via a remote control to receive extend and retract signals from the remote control, such that upon actuation of the remote control, the remote control unit energizes the linear actuator in the appropriate polarity to cause it to extend or retract.

Further, the first switch is biased towards an open position to prevent the linear actuator from being energized when force is not being applied to the first switch and simultaneously yielding control to the remote control unit.

In yet another aspect, the display mount includes a lockable telescoping cylinder assembly attached with the swing out apparatus to swing the front mount between a retracted position and an extended position. The lockable telescoping cylinder assembly includes an adjustment lever to unlock the lockable telescoping cylinder assembly. An adjustment handle is included to operate and adjust the display mount. A lock biasing spring is provided to bias the adjustment lever in the locked position. A counterbalancing mechanism is included to provide a sufficient holding force to hold the display mount and attached flat-panel display at a fully extended or fully retracted position and points in between. Additionally, at least one adjustment stop is attached to the lockable telescoping cylinder assembly such that when the front mount is at a predetermined lowest position, the swing out apparatus engages the adjustment stop, thereby preventing the front mount from being positioned below the predetermined lowest position.

Finally, as can be appreciated by one in the art, the present invention also comprises a method for forming and using the display mount described herein.

### BRIEF DESCRIPTION OF THE DRAWINGS

The objects, features and advantages of the present invention will be apparent from the following detailed descriptions of the various aspects of the invention in conjunction with reference to the following drawings, where:

FIG. 1 is an illustration of a prior art display mount;

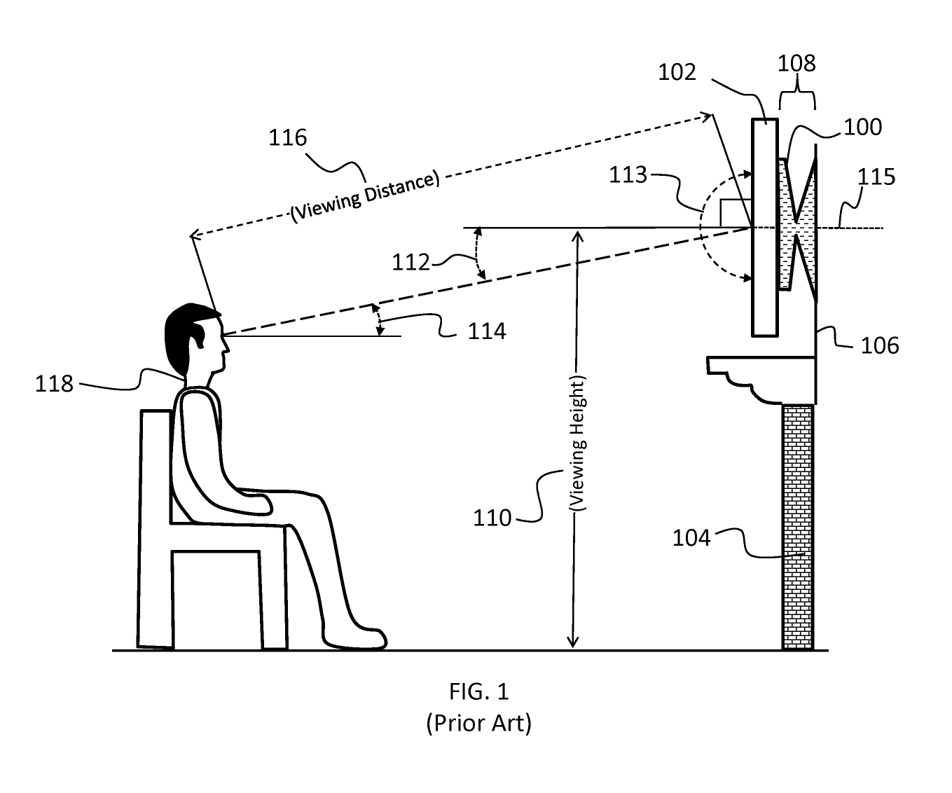

FIG. 2 is an illustration of a prior art display mount;

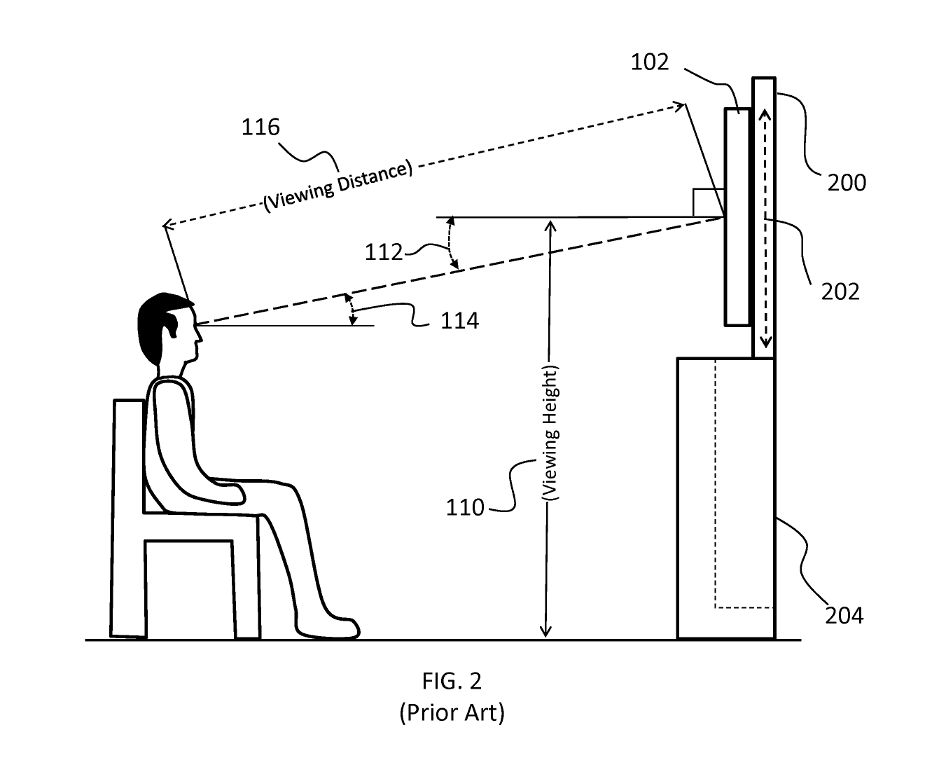

FIG. 3 is an illustration of a prior art display mount;

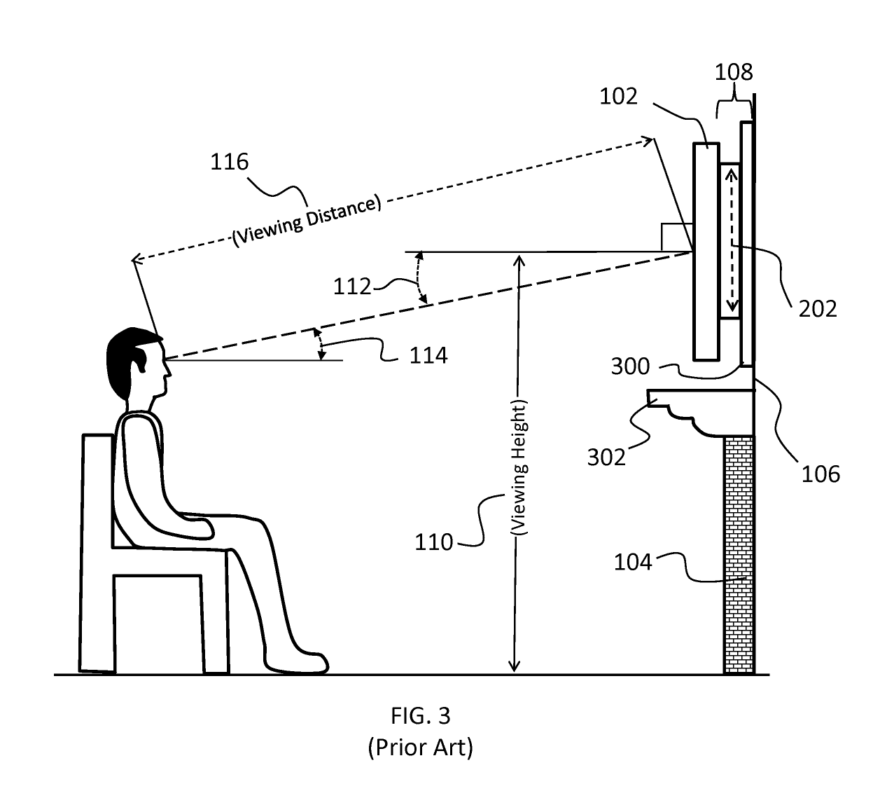

FIG. 4 is an illustration of a display mount according to the present invention, depicting the display mount in a retracted position;

FIG. 5 is an illustration of a display mount according to the present invention, depicting the display mount in an extended position;

FIG. 6 is front, isometric-view illustration of a display mount according to the present invention, depicting the display mount in an extended position;

FIG. 7 is an illustration of a display mount according to the present invention, depicting a television or flat panel display mounted to the display mount;

FIG. 8 is a rear, isometric-view illustration of the display mount according to the present invention;

FIG. 9 is a front-view illustration of the display mount according to the present invention;

FIG. 10 is a side-view illustration of the display mount according to the present invention;

FIG. 11 is a schematic depicting an electrical circuit wiring diagram for one electrical aspect of the present invention;

FIG. 12 is a bottom-view illustration of the display mount according to the present invention;

FIG. 13 is a rear, isometric-view illustration of the display mount according to the present invention, depicting a manual version;

FIG. 14 is a side-view illustration of the display mount according to the present invention, depicting the manual version; and

FIG. 15 is a front, isometric view illustration of one aspect of the mounting plate component of the present invention.

### DETAILED DESCRIPTION

The present invention relates to a display mount and, more particularly, to an adjustable flat-panel display mount for mounting the flat-panel to a surface and adjusting the viewing height and viewing direction of the flat-panel display. The following description is presented to enable one of ordinary skill in the art to make and use the invention and to incorporate it in the context of particular applications. Various modifications, as well as a variety of uses in different applications will be readily apparent to those skilled in the art, and the general principles defined herein may be applied to a wide range of embodiments. Thus, the present invention is not intended to be limited to the embodiments presented, but is to be accorded the widest scope consistent with the principles and novel features disclosed herein.

In the following detailed description, numerous specific details are set forth in order to provide a more thorough understanding of the present invention. However, it will be apparent to one skilled in the art that the present invention may be practiced without necessarily being limited to these specific details. In other instances, well-known structures and devices are shown in block diagram form, rather than in detail, in order to avoid obscuring the present invention.

The reader's attention is directed to all papers and documents which are filed concurrently with this specification and which are open to public inspection with this specification, and the contents of all such papers and documents are incorporated herein by reference. All the features disclosed in this specification, (including any accompanying claims, abstract, and drawings) may be replaced by alternative features serving the same, equivalent or similar purpose, unless expressly stated otherwise. Thus, unless expressly stated otherwise, each feature disclosed is only one example of a generic series of equivalent or similar features.

Furthermore, any element in a claim that does not explicitly state “means for” performing a specified function, or “step for” performing a specific function, is not to be interpreted as a “means” or “step” clause as specified in 35 U.S.C. Section 112, Paragraph 6. In particular, the use of “step of” or “act of” in the claims herein is not intended to invoke the provisions of 35 U.S.C. 112, Paragraph 6.

Please note, if used, the labels left, right, front, back, top, bottom, forward, reverse, clockwise and counter clockwise have been used for convenience purposes only and are not intended to imply any particular fixed direction. Instead, they are used to reflect relative locations and/or directions between various portions of an object.

Before describing the invention in detail, an introduction provides the reader with a general understanding of the present invention. Thereafter, specific details of the present invention are provided to give an understanding of the specific aspects and details.

(1) Introduction

As noted above, a problem with display mounts of the prior art is that they do not allow for an attached display to move out and down. In other words, existing display mounts do not enable a mounted flat-panel display to move downwards while simultaneously moving the flat-panel display away from the mounting point to avoid a fireplace mantel or other fixtures or objects on the wall. Thus, the present invention is directed to a display mount for adjusting the height and distance of a flat-panel display from a wall. More particularly, the present invention is related to an adjustable flat-panel display mount that allows the flat-panel display to be adjusted out, up and down while using minimal force. The adjustable flat-panel display mount may also employ a counterbalancing mechanism.

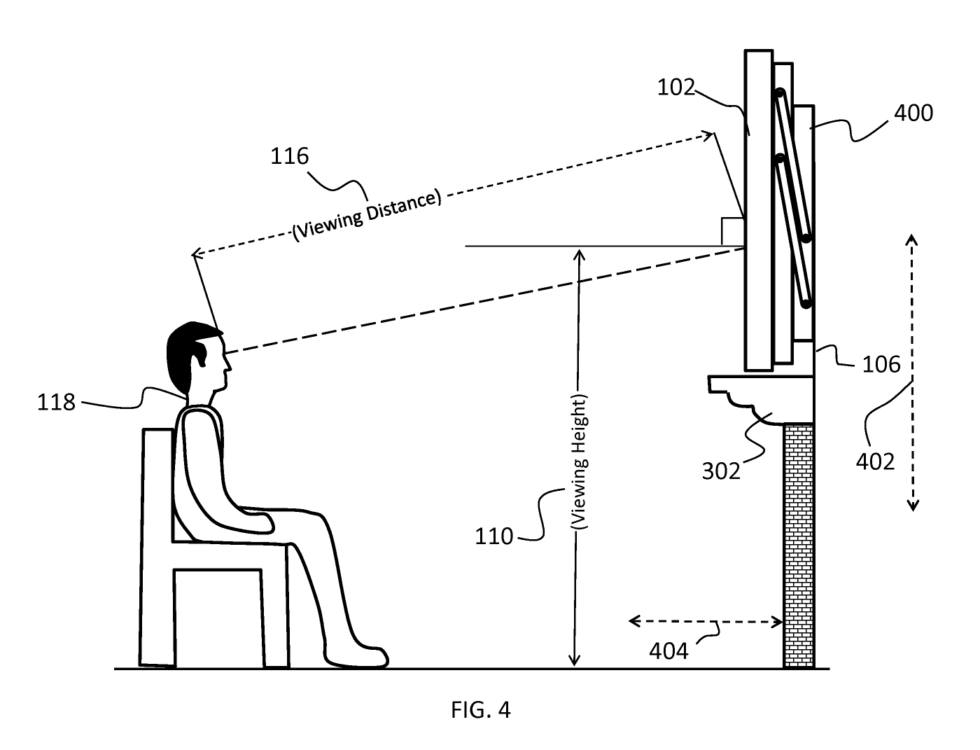

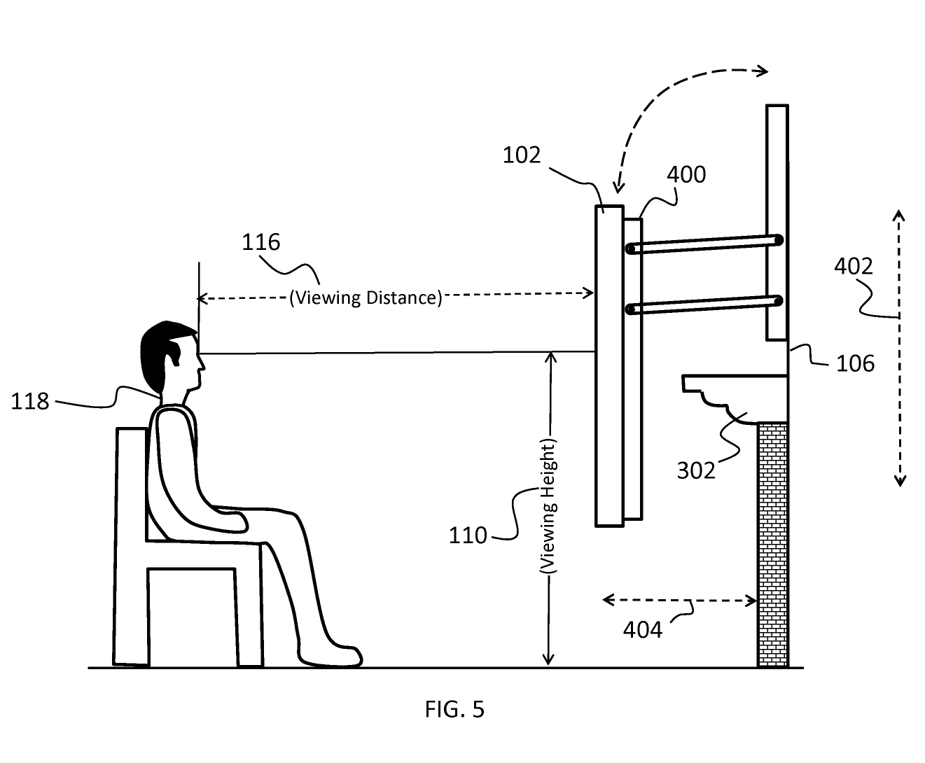

For example and as depicted in FIGS. 4 and 5, the present invention is a display mount 400 that can be adjusted vertically 402 and horizontally 404. The display mount 400 can be mounted at any suitable location, such as on a wall surface 106 and/or over a fireplace mantel 302. Due to its unique configuration, the display mount 400 enables a mounted flat-panel display 102 to move downwards while simultaneously moving the flat-panel display 102 away from the mounting point to avoid a fireplace mantel 302 or other fixtures or objects on the wall. The flat-panel display 102 can be lowered in front of the fireplace mantel 302 to a more comfortable viewing height 110 and viewing distance 116. As shown in FIG. 4, when the flat-panel display 102 is not being viewed or when the viewer 118 prefers to view the flat-panel display 102 at a higher viewing height 110, it can be returned to a position above the mantel 302 and adjacent to the wall 106.

From the foregoing, it will be appreciated that it would be an advancement in the art to provide a display mount 400 that can adjust the viewing height 110 of a flat-panel display 102 and also be practical for use over a fireplace mantel 302. It would be a further advantage to provide such a display mount 400 that could be adjusted quickly and with minimal effort. Finally, it would be an additional advantage to provide a way to easily position the flat-panel display 102 at a predetermined height and position above the fireplace mantel 302 and at a lower height and position in front of the mantel 302, or some position in between, for optimal viewing. Specific details of the present invention are provided below.

(2) Specific Details

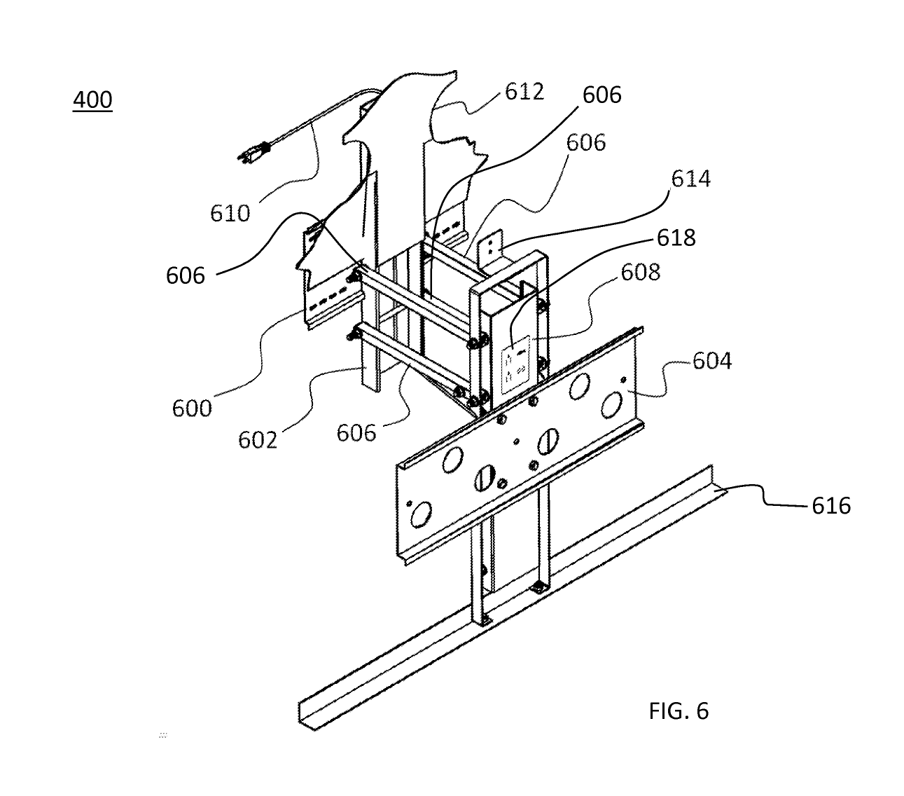

As shown in FIG. 6, the present invention is a display mount 400. The display mount 400 includes a mounting plate 600 for attaching the display mount 400 to a mounting surface (such as a wall or piece of furniture). At the other end is a front mount 604 that is formed to attach with a television display. As a non-limiting example, the front mount 604 is a mounting plate that provides a mounting point for the television display.

A rear casing 602 is attached with the mounting plate 600 to provide support for one end of a swing out apparatus. Importantly, the swing out apparatus is pivotally connected with the mounting plate 600, either directly or indirectly. If indirectly connected, the rear casing 602 is connected with and between the mounting plate 600 and the swing out apparatus.

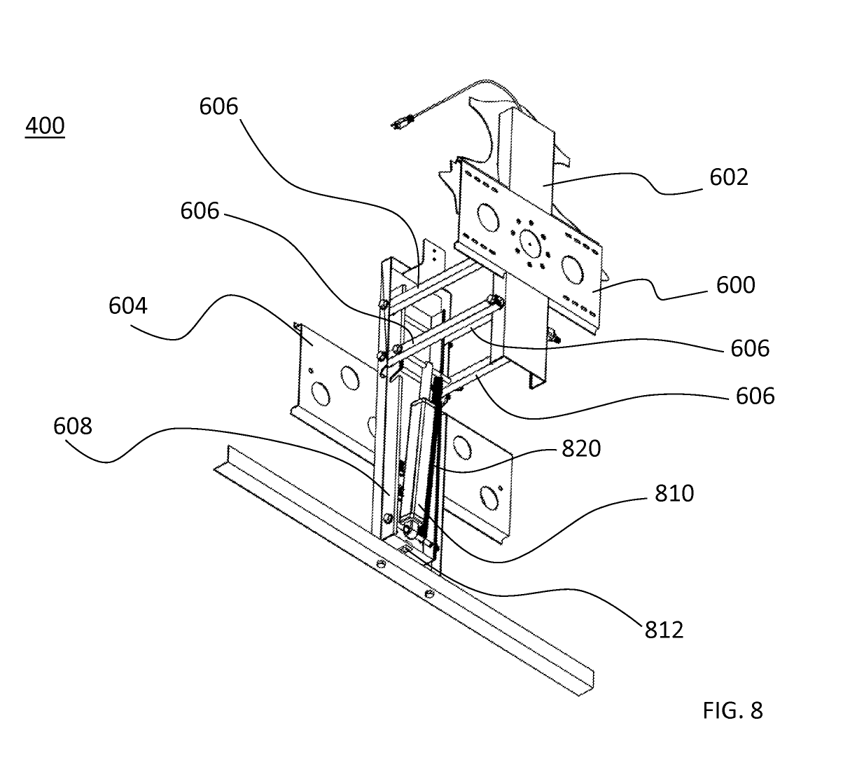

The swing out apparatus is pivotally connected between the rear casing 602 and the front mount 604 and is operable for moving the front mount 604 in any suitable direction of linear and/or rotational motion, or any combination thereof. For example, the swing out apparatus is formed to swing the front mount 604 out and down. As a non-limiting example, the swing out apparatus is a set of bars 606 (or a set of pivotally connected plates), a counterbalancing mechanism (depicted in FIG. 8), and electric and/or non-electric components used to control the extension and retraction of the display mount 400. The set of bars 606 together with the mounting plate 600/rear casing 602 and front mount 604/front casing 608, form a four-bar linkage. Bars 606 are pivotally connected at one end to the rear casing 602 and at the other end to the front mount 604 (or an intermediate structure or connection, such as front casing 608 as described in further detail below). The swing out apparatus allows the front mount 604 to pivot out from a retracted position (as depicted in FIG. 4) to an extended position (as depicted in FIGS. 5 and 6). The set of bars 606 are pivotally connected using any suitable connection technique, a non-limiting example of which includes bolts and nuts attached through pivot point holes. It should be noted that although a rear casing 602 is described and depicted, in another aspect, the swing out apparatus could be directly connected with the mounting plate 600. It should be noted that although front casing 608 is described and depicted, in another aspect, the swing out apparatus could be directly connected with front mount 604.

The rear casing 602 and front casing 608 can be used to hold and conceal components, such as components depicted in the electrical circuit diagram and components in the manual (non-electrical) version described in further detail below.

A decorative cover 612 can be attached with the rear casing 602 and/or mounting plate 600 to camouflage/decorate the mounting plate 600 and rear casing 602. This is important, as the rear casing 602 and mounting plate 600 may be visible when the display mount 400 is in the extended position.

A cable management plate 618 is incorporated into the front casing 608. The cable management plate 618 serves to assist with cable management. It serves as a connection point for wires that are routed through the display mount 400 and then connect to other devices. It also serves as a connection point for extension cables carrying electronic signals and can serve as a hub for some types of cables. When used to connect power cables, it can serve as a power outlet for multiple devices, therefore, reducing the number of cables that are run from the devices mounted on the front mount 604 and electronic accessory bracket 614 to their power source (e.g., via a plug-in cord 610). One aspect contains an opening to a conduit that is routed through the display mount 400. This is beneficial in that any current or future connectors of an adequate size can be accommodated without committing to a specific connector type. In one aspect, the cable management plate 618 is incorporated into the front mount 604. Additionally, the display mount 400 contains two cable management plates 618, one that is incorporated into front casing 608 and one that is incorporated into mounting plate 600 or rear casing 602 with wires and/or a conduit connected between them.

Also depicted is an electronic accessory bracket 614. The electronic accessory bracket 614 provides a mounting point for a variety of accessories, such as audio device accessories (e.g., center channel speaker, multiple speakers, speaker accessory, or microphone), video game accessories (e.g., video game console or video game interface accessory), internet accessories (e.g., video camera), and/or TV accessories. Further, as noted herein, the present invention provides a suitable mounting system for mounting a flat panel display above a fireplace mantel. In operation, heat can be generated from an operating fireplace that would rise and could possibly damage the flat panel display. Thus, it may be desirable to include a heat shield. In this aspect, a heat shield mount 616 is included. The heat shield mount 616 can be formed to operate as a heat shield or can serve as a mounting point upon which a heat shield can be attached.

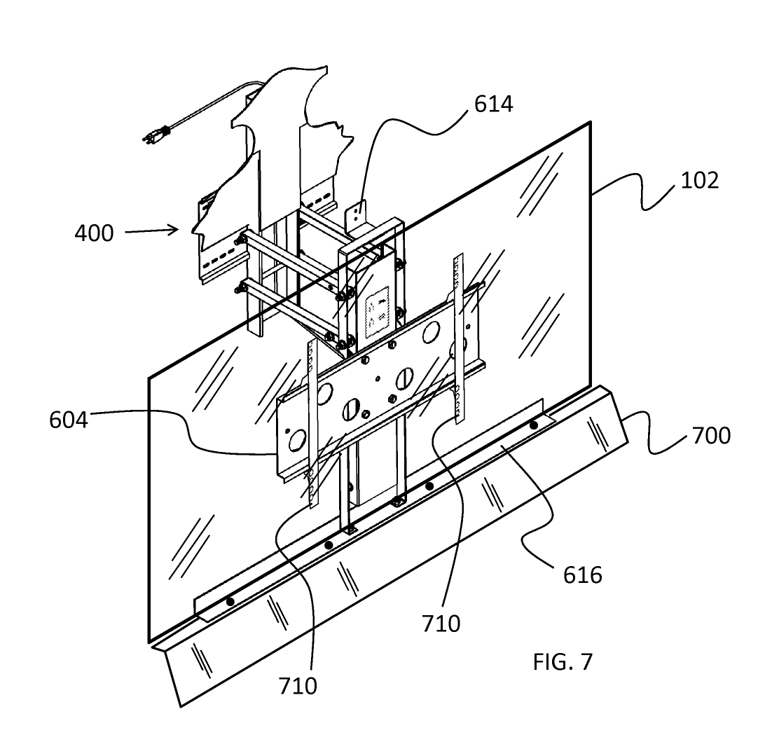

For further understating, FIG. 7 depicts the display mount 400 with a flat-panel display 102 attached to the front mount 604 using mounting brackets 710. The electronic accessory bracket 614 allows for accessories to be mounted such that they clear the top of the flat-panel display 102. Also depicted is a heat shield 700 that is attached with the heat shield mount 616. In one aspect, a retractable heat shield, similar to a retractable window shade, can be affixed between the heat shield mount 616 and the bottom of the rear casing 602.

FIG. 8 depicts a rear-view of an electric version of the display mount 400. In this aspect, the display mount 400 includes any suitable mechanism or device that allows for automated motion. As a non-limiting example, a linear actuator 810 is attached to two points on the four-bar linkage (composed of the set of bars 606, mounting plate 600/rear casing 602, and front mount 604/front casing 608), such that when the linear actuator 810 is extended or retracted, the front mount 604 pivots to the extended position (as depicted in FIG. 4) or the retracted position (as depicted in FIGS. 5 and 6) or some point in between. The extended or retracted position of the linear actuator 810, and hence the position of front mount 604, can be controlled via a control switch 812 mounted onto the front casing 608 or any other easily accessible location. In one aspect, the linear actuator 810 can be substituted with a winch mechanism that is attached between the rear casing 602 and front casing 608. The winch mechanism can release or retract a section of wire such that together with the gravitational force, the front casing 608 can be adjusted from the retracted position to the extended position or any point in between.

The display mount 400 may include a counterbalancing mechanism 820. As a non-limiting example, the counterbalancing mechanism can be comprised of any combination or number of tension springs, torsion springs, or gas springs. The counterbalancing force will be substantially equal to the gravitational force exerted by a flat-panel display that is mounted on the display mount 400 such that display mount 400 can be extended or retracted with minimal force when a flat-panel display is attached to it.

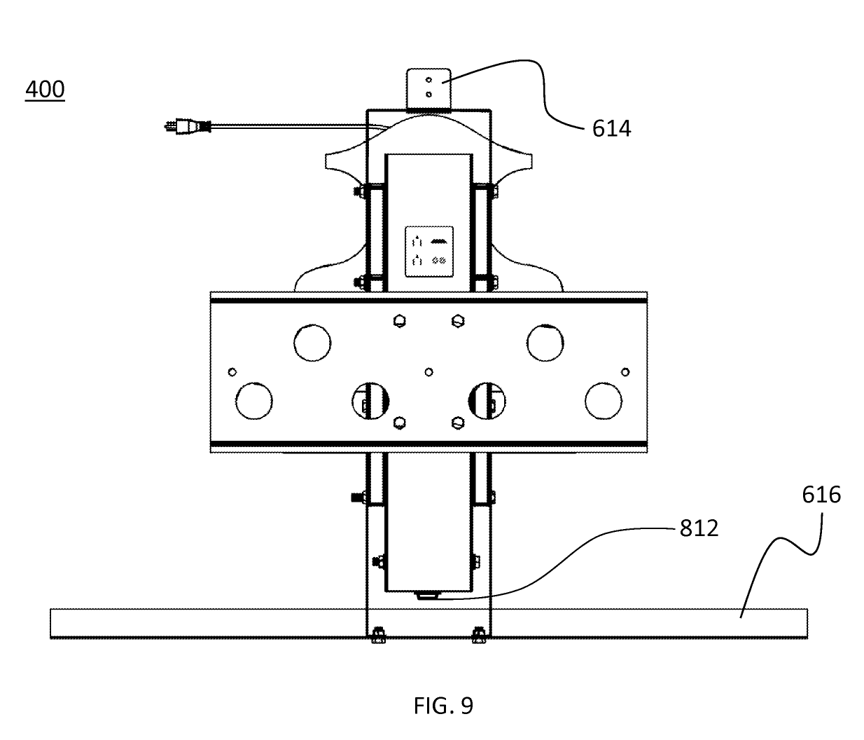

FIG. 9 depicts the front-view of the display mount 400 in the retracted position. When the display mount 400 is in the retracted position, the display will conceal most of the mount 400. The control switch 812 may be exposed along with the electronic accessory bracket 614 and heat shield mount 616.

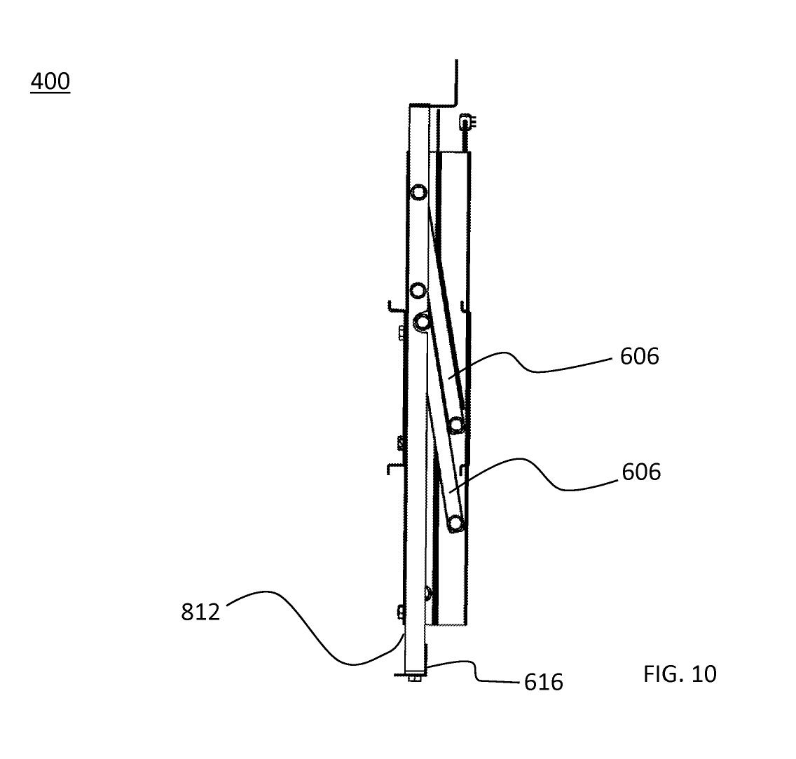

FIG. 10 depicts the side-view of the display mount 400 in the retracted position. The heat shield mount 616 provides protection for the display mount 400 and the flat panel display from heat while allowing access to the control switch 812. As shown, the two bars 606 depicted are positioned one directly above the other. In one aspect, the top and bottom bars 606 are offset such that they can rotate with reduced interference from each other and the display mount 400 can be retracted more compactly.

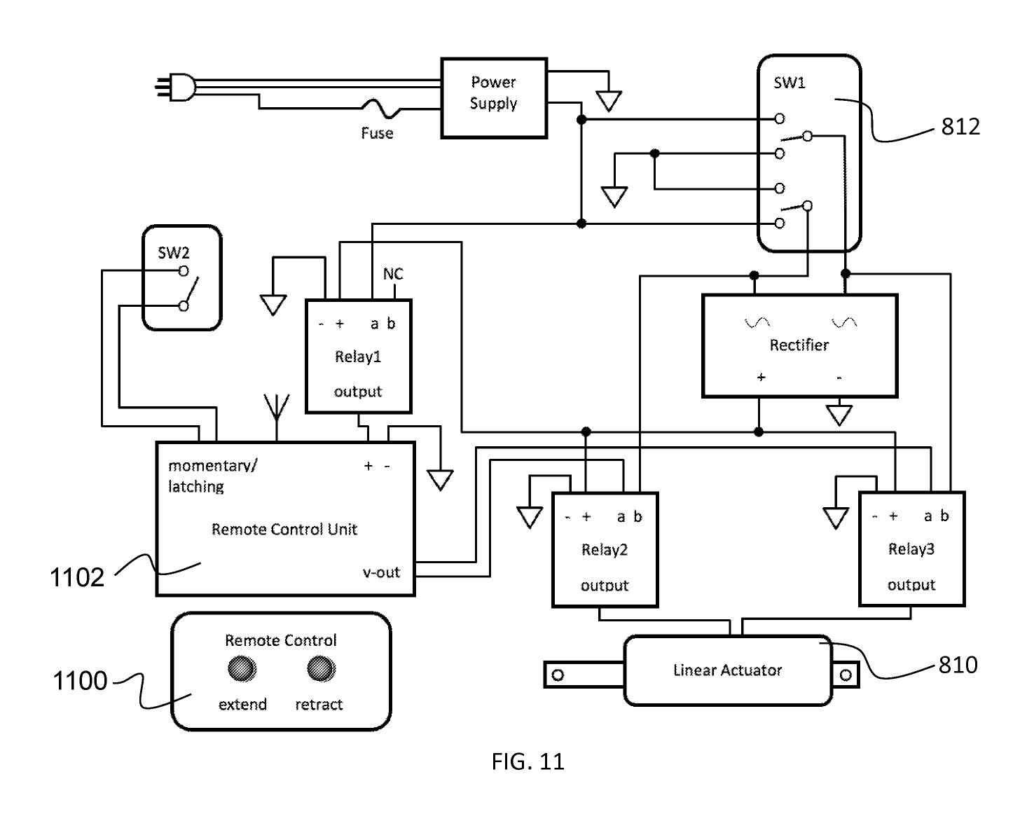

FIG. 11 is a schematic depicting an electrical circuit wiring diagram for one electrical aspect of the present invention. The display mount 400 can be extended or retracted by either pressing a switch incorporated into the display mount 400, a first switch SW1 (referred to as control switch 812 above), or by pressing a switch on a Remote Control 1100 that wirelessly communicates with a Remote Control Unit 1102. Switch SW1 is a double-pole double-throw switch, which can be wired to operate the Linear Actuator 810 in either polarity. For example, when the switch SW1 is pressed to one position, the Linear Actuator 810 extends and when the switch SW1 is pressed to the other position, the Linear Actuator 810 retracts. SW1 is biased towards an open position, which prevents the Linear Actuator 810 from being energized (or from moving) when force is not being applied to switch SW1 and simultaneously yields control to the Remote Control Unit 1102. When the Remote Control Unit 1102 is enabled and it receives a “extend” or “retract” signal from the Remote Control 1100, the Remote Control Unit 1102 will energize the Linear Actuator 810 in the appropriate polarity and cause it to extend or retract. The relays (Relay1, Relay2, and Relay3) ensure that the Linear Actuator 810 is energized through only one path of the circuit, either through the path of switch SW1 or through the path of the Remote Control Unit 1102. A second switch SW2 provides a setting for the Remote Control Unit 1102, making control of the Linear Actuator 810 either momentary or latching (momentary energizes the Linear Actuator 810 only while a button on the Remote Control Unit 1102 is pressed, latching energizes the Linear Actuator 810 with just one pulse of a button on the Remote Control 1100 and moves the Linear Actuator 810 until it reaches one of its two extreme positions—either fully extended or fully retracted). In this way, separate switches (SW1 and those on the Remote Control 1100) can seamlessly share control of the display mount 400. Switch SW1 has precedence over the control of the Linear Actuator 810.

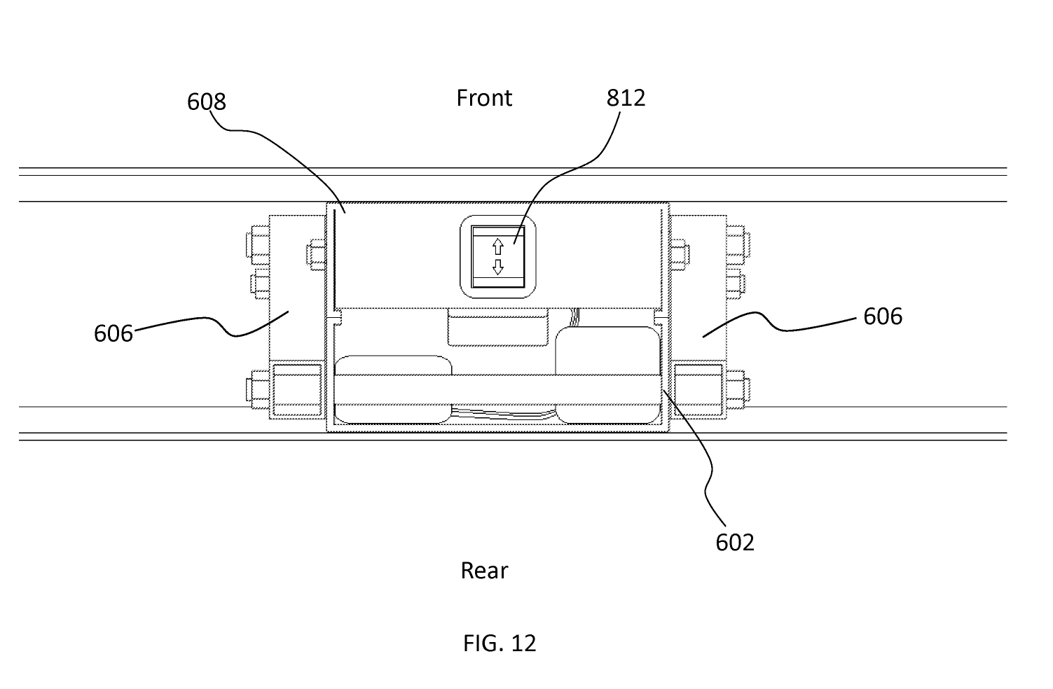

FIG. 12 is a schematic depicting the bottom-view of the display mount 400. It should be noted that for visual clarity, the heat shield is not illustrated in FIG. 12. The control switch 812 can be positioned at any suitable location, as a non-limiting example, the control switch 812 is positioned on the front casing 608 facing down for easy access. The rear casing 602 and front casing 608 come together when the display mount 400 is in the retracted position. In one aspect, the front casing 608 is broader than rear casing 602. When the display mount 400 reaches the retracted position, the front casing 608 straddles rear casing 602. Since the two pieces do not necessarily come in contact, this provides more flexibility with part tolerances. This also provides more options for the placement of bars 606. They can be placed outside both rear casings (rear casing 602 and front casing 608), inside one casing and outside the other, inside both casings, or any combination thereof.

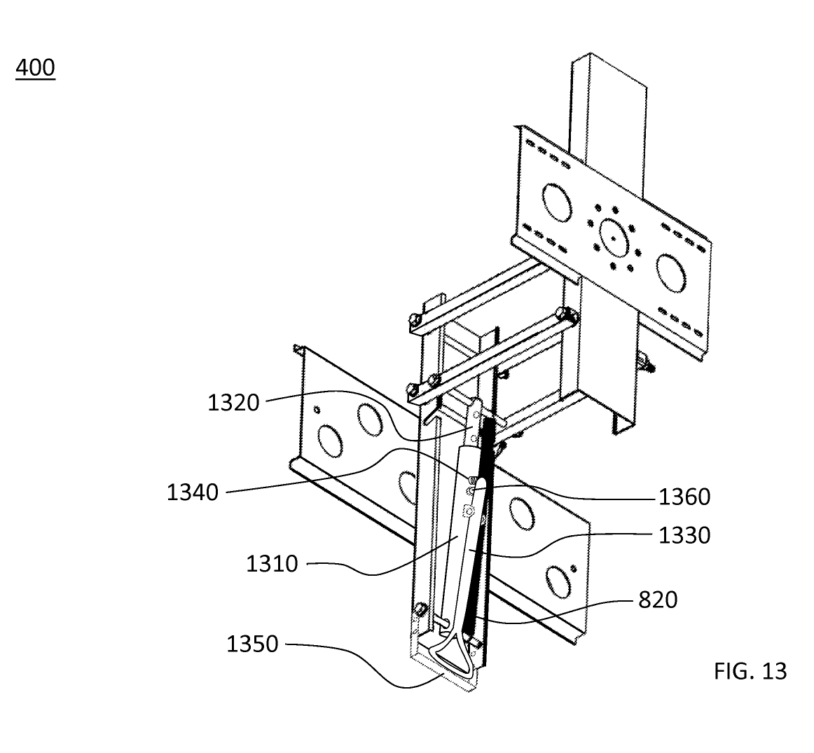

FIG. 13 is a schematic depicting the rear, isometric-view of a manual version of the display mount 400. As can be appreciated by one skilled in the art, in addition to being automated, the display mount 400 can be formed to be manually operated, as depicted in FIG. 13. Although optional accessories (such as the heat shield, electronic accessory bracket, cable management plate and decorative cover) are not depicted in FIG. 13, it should be understood that they can also be attached or built into the manual version of the display mount 400. The manual version includes a lockable telescoping cylinder assembly to allow extension and retraction of the display mount 400. The lockable telescoping cylinder assembly performs a similar function to the linear actuator 810 as shown in FIG. 8; as the lockable telescoping cylinder assembly is extended or retracted, the four-bar linkage is distorted to extend or retract the display mount 400. A non-limiting example of a suitable lockable telescoping cylinder assembly includes an outer cylinder 1310, an inner cylinder 1320, an adjustment lever 1330, and a lock biasing spring 1340. The inner cylinder 1320 is made to easily slide back and forth inside the outer cylinder 1310 and the two parts are shaped, or keyed, so that they cannot rotate with respect to each other. In addition, both the inner cylinder 1320 and the outer cylinder 1310 are shaped to include one or more stops to prevent the display mount from being positioned beyond predetermined fully retracted or fully extended positions. The adjustment lever 1330 is pivotally attached to the outer cylinder 1310 and includes a locking pin 1360 that locks the lockable telescoping cylinder assembly when the locking pin 1360 is inserted into any one of several spaced apertures on inner cylinder 1320. The outer cylinder 1310 includes an opening on its side that allows the locking pin 1360 to be inserted into the apertures on the inner cylinder. The lock biasing spring 1340 is attached to the adjustment lever 1330 and the outer cylinder 1310 and biases the lockable telescoping cylinder assembly towards the locked position. The adjustment handle 1350 can be used to adjust the display mount 400 and position the flat-panel display 102 in the desired location.

Both the electric and manual versions of the display mount 400 may include a counterbalancing mechanism 820.

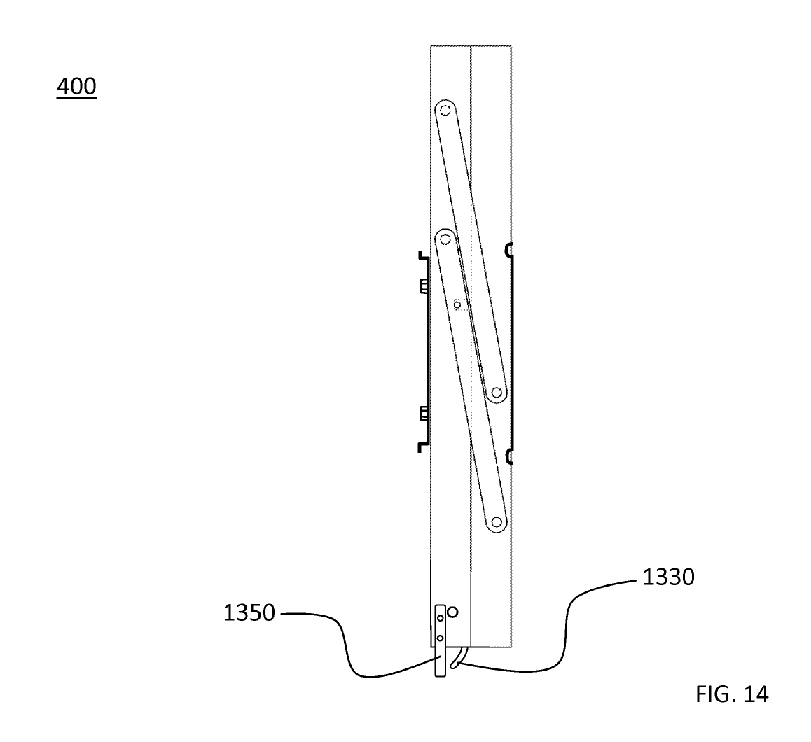

FIG. 14 is a schematic depicting the side-view of the manual version of the display mount 400. To operate the manual version, one end of the adjustment lever 1330 is pulled towards the adjustment handle 1350, thus unlocking the lockable telescoping cylinder assembly. The swing out apparatus can then be adjusted to the extended position, retracted position, or some point in between.

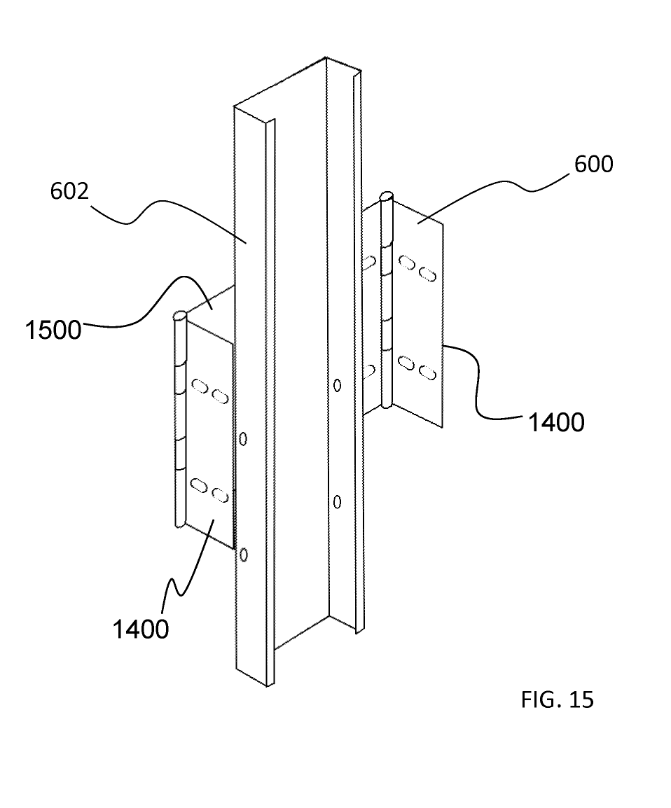

FIG. 15 is a depiction of one aspect of the mount plate 600 which is formed for optional in-wall installation. In this aspect, the mount plate 600 includes selectively positionable leaves 1400. The selectively positionable leaves 1400 are formed such that they can be selectively positioned between being substantially planar with a back portion 1500 of the mount plate 600 or perpendicular to the back portion 1500 of the mount plate 600 (or any relative position therebetween). A non-limiting example of such leaves 1400 includes two hinged side plates that are each pivotally attached with back portion 1500 that together form the mount plate 600. The rear casing 602 is shown to help establishing the orientation of the mount plate 600. When mounting the display mount 400 on a wall, the leaves 1400 can be turned to install the display mount 400 between two wall studs. By installing between the wall studs, the display mount 400 will not protrude away from the wall surface as much. This minimizes or eliminates the visible profile of the display mount 400.

What is claimed is:

1. A display mount, comprising:
a mounting plate for mounting with a surface;
a front mount formed to attach with a flat-panel display; and
a swing out apparatus pivotally connected between the mounting plate and the front mount, the swing out apparatus formed to swing the front mount between a retracted position and an extended position, such that motion from the retracted to extended position moves the front mount out and down.

2. The display mount as set forth in claim 1, wherein the swing out apparatus includes a set of bars that, together with the mounting plate and front mount, form a bar linkage.

3. The display mount as set forth in claim 2, further comprising a rear casing connected to and between the mounting plate and the swing out apparatus.

4. The display mount as set forth in claim 3, further comprising a front casing connected to and between the swing out apparatus and the front mount.

5. The display mount as set forth in claim 4, further comprising a heat shield connected with the front mount.

6. The display mount as set forth in claim 5, further comprising a linear actuator attached with the swing out apparatus to swing the front mount between a retracted position and an extended position.

7. The display mount as set forth in claim 6, further comprising a first switch attached with the front casing, the first switch operably connected with the linear actuator to allow for control of the linear actuator.

8. The display mount as set forth in claim 7, wherein the first switch is a double-pole, double-throw switch, which is wired to operate the linear actuator in both positive and negative polarities.

9. The display mount as set forth in claim 8, further comprising a remote control unit that is operably connected with the linear actuator, the remote control unit being controlled wirelessly via a remote control to receive extend and retract signals from the remote control, such that upon actuation of the remote control, the remote control unit energizes the linear actuator in the appropriate polarity to cause it to extend or retract.

10. The display mount as set forth in claim 9, wherein the first switch is biased towards an open position to prevent the linear actuator from being energized when force is not being applied to the first switch and simultaneously yielding control to the remote control unit.

11. The display mount as set forth in claim 10, wherein the swing out apparatus further comprises a counterbalancing mechanism, the counterbalancing mechanism providing a counterbalancing force that is substantially equal to a gravitational force exerted by a flat-panel display when mounted on the display mount.

12. The display mount as set forth in claim 1, further comprising a rear casing connected to and between the mounting plate and the swing out apparatus.

13. The display mount as set forth in claim 1, further comprising a front casing connected to and between the swing out apparatus and the front mount.

14. The display mount as set forth in claim 1, further comprising a heat shield connected with the front mount.

15. The display mount as set forth in claim 1, further comprising a linear actuator attached with the swing out apparatus to swing the front mount between a retracted position and an extended position.

16. The display mount as set forth in claim 15, further comprising a first switch attached with the display mount, the first switch operably connected with the linear actuator to allow for control of the linear actuator.

17. The display mount as set forth in claim 16, wherein the first switch is a double-pole, double-throw switch, which is wired to operate the linear actuator in both positive and negative polarities.

18. The display mount as set forth in claim 15, further comprising a remote control unit that is operably connected with the linear actuator, the remote control unit being controlled wirelessly via a remote control to receive extend and retract signals from the remote control, such that upon actuation of the remote control, the remote control unit energizes the linear actuator in the appropriate polarity to cause it to extend or retract.

19. The display mount as set forth in claim 18, further comprising a first switch attached with the display mount, the first switch operably connected with the linear actuator to allow for control of the linear actuator, and wherein the first switch is biased towards an open position to prevent the linear actuator from being energized when force is not being applied to the first switch and simultaneously yielding control to the remote control unit.

20. The display mount as set forth in claim 1, wherein the swing out apparatus further comprises a counterbalancing mechanism, the counterbalancing mechanism providing a counterbalancing force that is substantially equal to a gravitational force exerted by a flat-panel display when mounted on the display mount.

21. The display mount as set forth in claim 1, wherein the mounting plate has a back portion and selectively positionable leaves, the selectively positionable leaves being formed such that they can be selectively positioned between being substantially planar with a back portion of the mount plate or perpendicular to the back portion of the mount plate, or any relative position therebetween.

22. The display mount as set forth in claim 1, further comprising a lockable telescoping cylinder assembly attached with the swing out apparatus to swing the front mount between a retracted position and an extended position.

23. The display mount as set forth in claim 22, wherein the lockable telescoping cylinder assembly further comprises:
adjustment lever to unlock the lockable telescoping cylinder assembly;
adjustment handle to operate and adjust the display mount;
a lock biasing spring formed to bias the adjustment lever in the locked position;
a counterbalancing mechanism formed to provide a sufficient holding force to hold the display mount and attached flat-panel display at a fully extended or fully retracted position and points in between; and
at least one adjustment stop attached to the lockable telescoping cylinder assembly such that when the front mount is at a predetermined lowest position, the swing out apparatus engages the adjustment stop, thereby preventing the front mount from being positioned below the predetermined lowest position.

24. A display mount, comprising:
a mounting plate for mounting with a surface, the mounting plate having a back portion and selectively positionable leaves, the selectively positionable leaves being formed such that they can be selectively positioned between being substantially planar with a back portion of the mount plate or perpendicular to the back portion of the mount plate, or any relative position therebetween; and
a front mount formed to attach with a flat-panel display; and
a swing out apparatus pivotally connected between the mounting plate and the front mount, the swing out apparatus formed to move the front mount in a motion selected from a group consisting of linear motion and rotational motion, or any combination thereof.

25. The display mount as set forth in claim 24, wherein the selectively positionable leaves are hinged side plates that are pivotally connected with the back portion of the mounting plate.
